(19) United States
(12) Patent Application Publication
(10) Pub. No.: US 2026/0320949 A1
(43) Pub. Date: Oct. 15, 2026

(54) Apparatus and Method for Comparative Display of 3D Models

(71) Applicant: CUPIX, INC., Gyeonggi-do (KR)

(72) Inventors: SeockHoon BAE, Gyeonggi-do (KR); ChangYoon YANG, Seoul (KR)

(73) Assignee: CUPIX, INC., Gyeonggi-do (KR)

(21) Appl. No.: 19/635,680

(22) Filed: Mar. 31, 2026

(30) Foreign Application Priority Data
Apr. 10, 2025 (KR) 10-2025-0046749

(51) Int. Cl. G06T 19/20

(52) U.S. Cl. CPC G06T 19/20; G06T 2210/04; G06T 2210/62; G06T 2219/2004

(57) ABSTRACT

Provided are an apparatus and method for comparatively displaying three-dimensional models to facilitate an effective comparison between different three-dimensional models representing a three-dimensional structure of an object in the same target space. Because two three-dimensional models are directly compared with each other with respect to corresponding positions, gaze movement occurring in the related-art split-screen methods may be minimized, thereby improving the intuitiveness of comparison. That is, by facilitating a partial superimposition comparison at corresponding positions, the advantages of simultaneously enhancing intuitiveness, accuracy, and user convenience are provided.

### CROSS-REFERENCE TO RELATED APPLICATION

This application is based on and claims priority under 35 U.S.C. § 119 to Korean Patent Application No. 10-2025-0046749, filed on Apr. 10, 2025, in the Ministry of Intellectual Property, Republic of Korea, the disclosure of which is incorporated by reference herein in its entirety.

### BACKGROUND

### Technical Field

The present disclosure relates to an apparatus and method for comparatively displaying three-dimensional models to facilitate an effective comparison between different three-dimensional models representing a three-dimensional structure of an object in the same target space.

### Related Art

In recent years, there has been an increasing demand in various fields, such as construction, manufacturing, cultural heritage conservation, and virtual reality, to compare and analyze a plurality of three-dimensional models generated at different points in time or for different purposes for the same target space. For example, it is necessary to compare a design model (building information model (BIM) data) with an actual construction result (as-built data) or to compare multiple sets of scan data obtained at different points in time to identify changes.

In the related art, a split-screen or side-by-side method, in which two models are separately displayed by partitioning a screen horizontally or vertically, is primarily employed to compare such a plurality of three-dimensional models.

However, such methods suffer from a drawback in that a user needs to repeatedly shift their line of sight to compare identical positions across the models, as the models are displayed in discrete regions. This reduces the efficiency of the comparison operation and makes it difficult to intuitively recognize subtle discrepancies.

Furthermore, related-art technologies lack the means to selectively compare models within a particular region of interest, resulting in an inefficient comparison process that relies on the entire screen.

Accordingly, there is a need for a novel display and comparison technology that enables an intuitive comparison of a plurality of three-dimensional models for the same target space with respect to corresponding positions, while allowing a user to select a region of interest for efficient comparison.

### SUMMARY

Provided is a display technology that enables a more intuitive and efficient comparison of a plurality of three-dimensional models for the same target space.

Additional aspects will be set forth in part in the description which follows and, in part, will be apparent from the description, or may be learned by practice of the presented embodiments of the disclosure.

According to an aspect of an embodiment, an apparatus for comparatively displaying three-dimensional models, for displaying a target space by using first model data and second model data that represent a three-dimensional structure of an object within the same target space, includes a receiving module configured to receive and store the first model data and the second model data, an alignment module configured to align the first model data and the second model data with each other in the same coordinate system, a first window display module configured to display a model based on the first model data, on a first display window of the display device, and a second window display module configured to display a model based on the second model data, which is aligned with the first model data in the same coordinate system, on a second display window, such that the model based on the second model data is superimposed at a position corresponding to a partial region of the first display window.

According to an aspect of another embodiment, a method of comparatively displaying three-dimensional models, for displaying a target space on a display device by using first model data and second model data that represent a three-dimensional structure of an object within the same target space, includes (a) receiving and storing, by a receiving module, the first model data and the second model data, (b) aligning, by an alignment module, the first model data and the second model data with each other in the same coordinate system, (c) displaying, by a first window display module, a model based on the first model data, on a first display window of the display device, and (d) displaying, by a second window display module, a model based on the second model data, which is aligned with the first model data in the same coordinate system, on a second display window, such that the model based on the second model data is superimposed at a position corresponding to a partial region of the first display window.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an overall configuration of an apparatus for comparatively displaying three-dimensional models, according to an embodiment of the present disclosure;

FIG. 2 is a flowchart for describing a process of performing a method of comparatively displaying three-dimensional models according to the present disclosure by the apparatus for comparatively displaying three-dimensional models illustrated in FIG. 1; and

FIGS. 3 to 6 are diagrams illustrating examples in which three-dimensional models are displayed on a screen by the apparatus and method for comparatively displaying three-dimensional models, according to the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, preferred embodiments of the present disclosure will be described in detail with reference to the accompanying drawings.

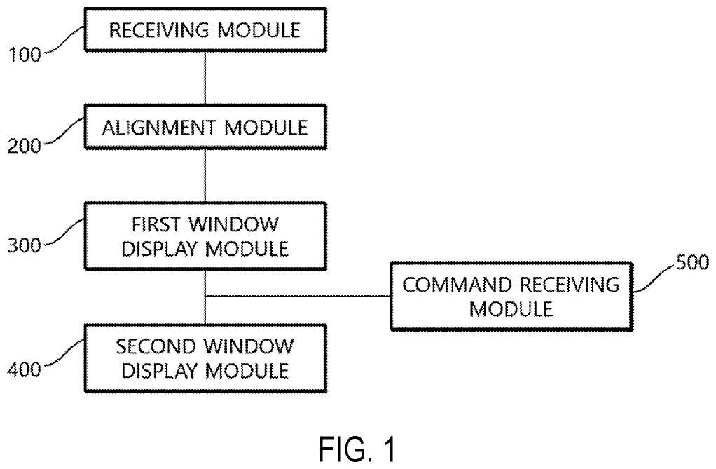

Referring to FIG. 1, an apparatus for comparatively displaying three-dimensional models of the present disclosure may include a receiving module 100, an alignment module 200, a first window display module 300, a second window display module 400, a command receiving module 500, a display device, and an input device.

The receiving module 100 receives and stores first model data and second model data for the same target space from an external source. The first model data and the second model data may be implemented in various forms, such as three-dimensional point cloud data, mesh data, Gaussian splatting data, or 360-degree virtual tour data.

In the present embodiment, a description will be provided by taking an example in which the first model data is three-dimensional model data obtained by capturing a construction state (as-built) of a construction site and the second model data is a building information model (BIM) representing a design intent.

The alignment module 200 aligns the first model data and the second model data with each other in the same coordinate system. Here, the alignment may be performed by using feature points or feature surfaces, or through an optimization-based method such as an iterative closest point (ICP) algorithm. In addition, when the two model data have different scales (dimensional ratios), the alignment module 200 may match the dimensional ratios between them by scaling one model data with respect to the other model data as necessary. This scale correction process allows for accurate position alignment even between model data generated with different measurement standards or resolutions, thereby improving the reliability of comparison results.

The first window display module 300 displays a model based on the aligned first model data on a first display window 610 of the display device. The display device is generally a computer monitor, and the first display window 610 is displayed on a screen of the monitor.

The second window display module 400 displays a model based on the second model data on a second display window 620 of the display device. Here, the second window display module 400 displays the second display window 620 such that the second display window 620 is superimposed at a position corresponding to a partial region of the first display window 610. The second window display module 400 displays, on the second display window 620, the second model data corresponding to the first model data of a region overlapping with the first display window 610. Accordingly, the second window display module 400 displays the second model data having the same position and orientation as the region of the first display window 610 overlapping with the second display window 620, thereby enabling an effective comparison between the first model data and the second model data with respect to corresponding positions.

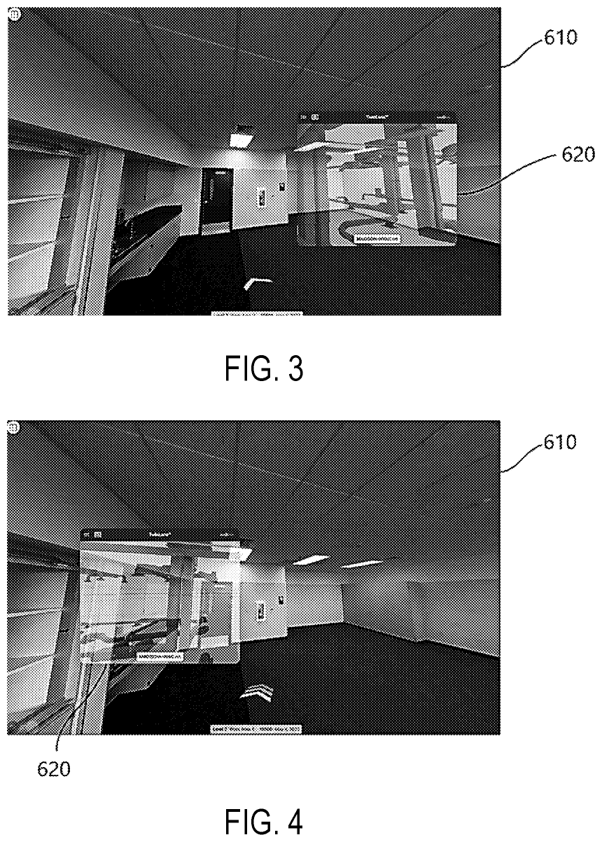

FIG. 3 illustrates an example in which three-dimensional models are displayed on a display device by the apparatus for comparatively displaying three-dimensional models illustrated in FIG. 1.

Referring to FIG. 3, first model data is displayed in its entirety on the first display window 610, the second display window 620 is displayed so as to be superimposed on a partial region of the first display window 610, and second model data is displayed inside the second display window 620. Accordingly, a user may intuitively identify discrepancies between the two models through a comparison with respect to corresponding positions.

The command receiving module 500 may receive a command to adjust the position, size, and transparency of the second display window 620 from the user through an input device such as a mouse or a keyboard.

The second window display module 400 may adjust the position of the second display window 620 according to the position adjustment command, and may adjust the size of the second display window 620 according to the size adjustment command. In addition, the second window display module 400 may adjust the transparency of the second display window 620 according to the transparency adjustment command such that the first display window 610 in the background is visible through the second display window 620.

The user may move the second display window 620 to a desired position, adjust the size of the second display window 620, or adjust the transparency of the second display window 620 through an input device such as a mouse or a keyboard, thereby freely selecting a target region for comparison.

The second window display module 400 adjusts the position and size of the second display window 620 according to a user command received by the command receiving module 500, and then displays the second display window 620 so as to be superimposed on the first display window 610. In addition, when the user adjusts the transparency of the second display window 620 via a user interface (UI) provided by the command receiving module 500, the second window display module 400 adjusts the transparency of the second display window 620 according to the adjusted transparency received by the command receiving module 500, such that the second display window 620 is displayed so as to be superimposed on an image displayed in the first display window 610 as a background.

Here, the first window display module 300 and the second window display module 400 display the first display window 610 and the second display window 620 in conjunction with each other to maintain the same viewpoint. In more detail, when the viewpoint of the first model data displayed on the first display window 610 is changed according to a user input or system control, and the position, orientation, or zoom level of the model based on the first model data is thus changed, the second window display module 400 changes a rendering viewpoint of the second model data displayed on the second display window 620 to correspond to the changed viewpoint information.

For example, when a user changes the viewing direction by moving or rotating a camera on the first display window 610, or changes the viewing distance through a zoom manipulation, the second model data displayed on the second display window 620 may also be updated in conjunction with the change in position and orientation according to the same reference coordinate system and the same viewpoint conditions. Accordingly, the second model data displayed on the second display window 620 continuously maintains spatial correspondence in position and orientation corresponding to the first model data displayed on the first display window 610. Thus, because the user may confirm that a comparison target in the second display window 620 always corresponds at the same viewpoint while changing a position of interest in the first display window 610, it is possible to reduce misinterpretations or comparison errors caused by viewpoint discrepancies, and to more accurately identify differences in the geometry, position, or construction state of a particular object.

In addition, even when the user adjusts the position and size of the second display window 620 with respect to the first display window 610, the second model data displayed on the second display window 620 is also updated in conjunction with the change in position and orientation according to the same reference coordinate system and the same viewpoint conditions as those of the first display window 610. Accordingly, the second model data displayed on the second display window 620 continuously maintains a model of the same position and the same orientation spatially corresponding to the first model data displayed on the first display window 610. Thus, the user may confirm that the comparison target in the second display window 620 always corresponds to the first model data of the corresponding region at the same viewpoint while changing the position of interest in the second display window 620 with respect to the first display window 610.

The second window display module 400 may display a model based on the second model data only in a portion corresponding to the region where the second display window 620 overlaps with the first display window 610, and may restrict display in other regions than the overlapping region through at least one of masking, clipping, and transparency adjustment. Accordingly, the second display window 620 operates as a virtual lens, and only the model based on the first model data is solely displayed in the remaining region of the first display window 610, excluding the second display window 620.

In addition, the second window display module 400 may display the model based on the second model data through different colors, outline display, or transparency settings such that the model based on the second model data is visually distinguished from the model based on the first model data within the second display window 620.

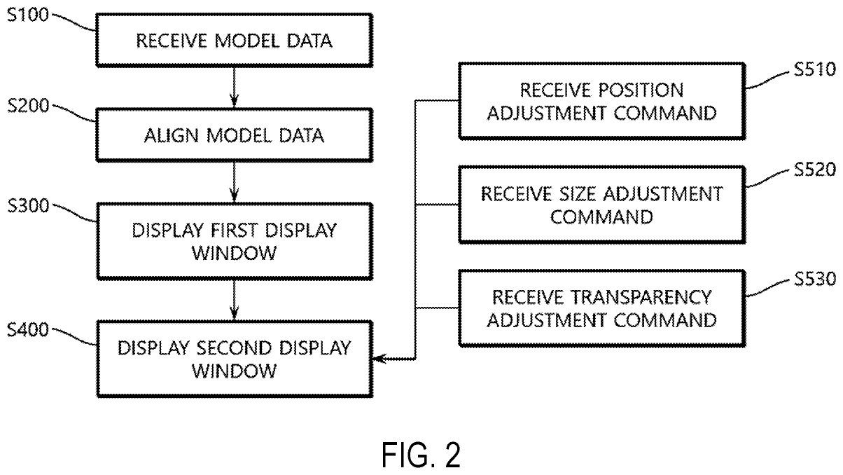

Hereinafter, an example of performing a method of comparatively displaying three-dimensional models according to the present disclosure by using the apparatus for comparatively displaying three-dimensional models configured as described above will be described. FIG. 2 is a flowchart for describing a process of performing a method of comparatively displaying three-dimensional models according to the present disclosure by the apparatus for comparatively displaying three-dimensional models illustrated in FIG. 1.

First, the receiving module 100 receives and stores first model data and second model data for the same target space (operation (a); S100). As such, by obtaining a plurality of sets of model data generated at different points in time or for different purposes, a foundation for subsequent comparative analysis is established.

Next, the alignment module 200 aligns the first model data and the second model data with each other in the same coordinate system (operation (b); S200). This process may resolve positional discrepancies between models having different reference coordinate systems, and enable an accurate comparison with respect to corresponding positions. As described above, the alignment module 200 may match the dimensional ratios between the two model data by scaling one model data with respect to the other model data as necessary.

Subsequently, the first window display module 300 displays a model based on the first model data on the first display window 610 (operation (c); S300). In this operation, the first model is displayed on the entire screen as a reference model, serving to enable the user to grasp the overall structure of the target space. In the present embodiment, the first window display module 300 displays model data of an actual construction state (as-built) of the construction site on the first display window 610, so as to allow the user to readily identify the progress of construction.

Next, the second window display module 400 displays a model based on the second model data on the second display window 620 such that the model is superimposed at a position corresponding to a partial region of the first display window 610 (operation (d); S400). In the present embodiment, as described above, the second window display module 400 displays a BIM representing a design intent on the second display window 620. When the user intends to check the BIM data of the first model data displayed on the first display window 610, the user may effectively check the second model data for the corresponding position as the second display window 620 is displayed so as to be superimposed on the corresponding region. Accordingly, while checking the BIM data in real-time, the user may easily confirm whether a building is being constructed according to the design based on as-built data.

Compared to related-art methods, such as alternating between physical drawings and a computer screen or performing a side-by-side comparison in a split-screen view, the present disclosure enables a significantly more effective and intuitive visual comparison of two models. In particular, unlike the related-art side-by-side split-screen methods, the present disclosure eliminates the need for the user's gaze to move back and forth between two views, thereby reducing user fatigue and enhancing the efficiency of comparison, review, and verification tasks.

In addition, when the command receiving module 500 receives a position adjustment command for the second display window 620 through the input device (operation (e); S510), the second window display module 400 adjusts the position of the second display window 620 according to the position adjustment command, and displays the second display window 620. Through this, the user may freely reposition the region of interest for comparison, which has the effect of enhancing comparison efficiency. FIG. 3 illustrates the first display window 610 and the second display window 620 before a position adjustment, and FIG. 4 illustrates the first display window 610 and the second display window 620 in a state where the position of the second display window 620 has been adjusted according to a position adjustment command.

In addition, when the command receiving module 500 receives a size adjustment command for the second display window 620 through the input device (operation (f); S520), the second window display module 400 adjusts the size of the second display window 620 according to the size adjustment command, and displays the second display window 620. Accordingly, it is advantageous in that the display area for the first model data and the second model data may be easily adjusted by enlarging or reducing the comparison area.

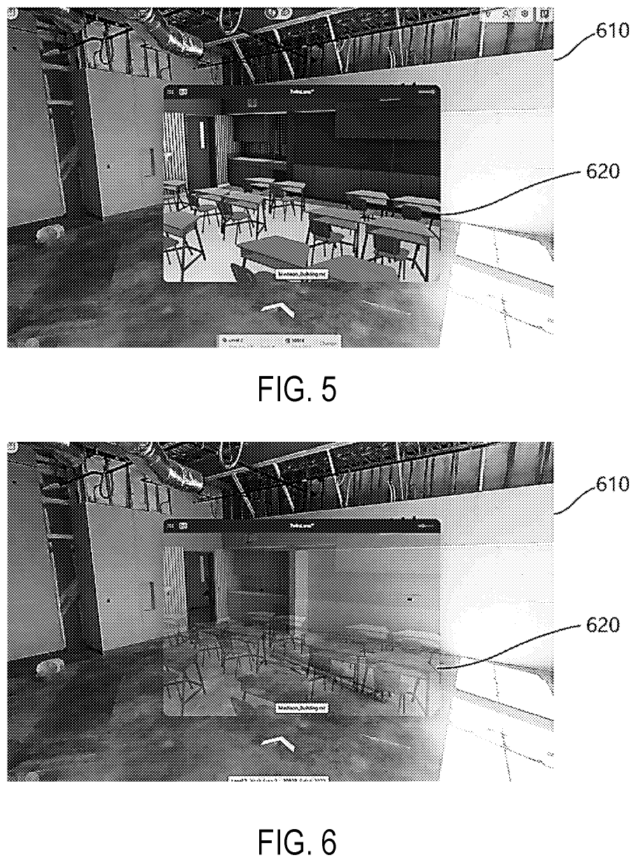

In addition, when the command receiving module 500 receives a transparency adjustment command for the second display window 620 through the input device (operation (g); S530), the second window display module 400 adjusts the transparency of the second display window 620 according to the transparency adjustment command, and displays the second display window 620. This enables the two models to be visually superimposed, thereby allowing for a clearer perception of any discrepancies between them. FIG. 5 illustrates the first display window 610 and the second display window 620 before a transparency adjustment, and FIG. 6 illustrates the first display window 610 and the second display window 620 in a state where the transparency of the second display window 620 has been adjusted according to a transparency adjustment command. As the transparency of the second display window 620 is increased, as illustrated in FIG. 6, it may be confirmed that the image of the first display window 610 in the background is also visible through the second display window 620.

In this case, operations (c) and (d) are performed in conjunction with each other such that the same viewpoint is maintained. In more detail, when the viewpoint of the first model data displayed on the first display window 610 is changed by a user manipulation such that the position, orientation, or magnification of the first model data on the screen is changed, the second window display module 400 synchronously updates the position, orientation, and display state of the second model data displayed on the second display window 620 to reflect the same viewpoint change.

For example, when the user performs a rotation, movement, or zoom manipulation relative to the first display window 610, the second model data in the second display window 620 is also changed to be displayed from an identical viewing direction and at an identical viewing distance in response thereto.

As such, when the first display window 610 and the second display window 620 are synchronized at the same viewpoint, a particular surface or a specific portion of an object viewed by the user in the first display window 610 is displayed in the second display window 620 in correspondence with the same orientation and positional relationship, thereby enabling the user to verify geometric or positional differences between the two models through direct correspondence. Accordingly, this prevents comparison errors caused by viewpoint discrepancies between the two models and is advantageous in that the user may continuously compare regions of interest without the need for repetitive manual readjustment of the screen.

Furthermore, in a case where the second model data includes design information (BIM data), the position and structure of internal piping, electrical installations, or other buried facilities within a wall, which are not visible in the first model data (e.g., the as-built state), may be identified through the second display window 620. For example, when the user moves the second display window 620 to an area where a wall exists, information about facilities situated behind the structure, which is obscured in the first model data, is visually provided by the second model data, allowing the user to intuitively identify the locations of hidden facilities. Accordingly, it is advantageous in that the understanding of occluded areas may be improved during maintenance, inspection, or construction verification processes.

Furthermore, in operation (d), the second model data may be displayed through visual differentiation means such as color, outlines, or transparency. Accordingly, it is possible to more easily identify discrepancies between the two models.

Consequently, the method according to the present disclosure provides the advantage of simultaneously enhancing intuitiveness, accuracy, and user convenience by comparing models through partial superimposition at corresponding positions.

Although the present disclosure has been described above with preferred examples, the scope of the present disclosure is not limited to the embodiments described above.

For example, although the foregoing description has been given with respect to a case where the first model data is as-built data and the second model data is BIM data, the types of the first model data and the second model data to be compared with each other are not limited thereto and may be modified into various other forms. That is, the first model data and the second model data may each include drawing data, internal structural geometries of a vessel, or model data representing the landscaping of a park. In some cases, it is also possible to implement the present disclosure to compare three or more sets of model data by additionally receiving third model data during the comparison of the first model data and the second model data and applying the same technical features as described above. Furthermore, in some cases, the present disclosure may be implemented such that the first model data or the second model data is replaced or modified with another type of model data during the comparison process.

In addition, in some cases, the apparatus and method for comparatively displaying three-dimensional models according to the present disclosure may be implemented such that two or more second model display windows are displayed so as to be superimposed over a first model display window.

In addition, although the foregoing description has explained that the command receiving module 500 receives a command to adjust the position, size, and transparency of the second display window 620 and the second window display module 400 modifies the second display window 620 accordingly, the present disclosure may be implemented to adjust only any one of the position, size, and transparency, or to modify the second display window 620 by receiving a command to change other visual elements in addition to the position, size, and transparency.

According to the present disclosure, after aligning first model data and second model data for the same target space in the same coordinate system, the first model is displayed on a full screen and the second model is superimposed to correspond to a partial region of the first model, thereby achieving the following effects.

First, because the two models are directly compared with each other with respect to corresponding positions, gaze movement occurring in the related-art split-screen methods may be minimized, thereby improving the intuitiveness of comparison.

Second, because the position, size, and transparency of the second display window may be adjusted according to a user input, a user may selectively enlarge or reduce a desired area for comparison, thereby enhancing the flexibility and efficiency of the comparison process.

Third, as the first display window and the second display window are interlocked to maintain the same viewpoint, comparison errors caused by viewpoint discrepancies may be prevented, and more accurate comparison results may be provided.

Fourth, by applying visual differentiation means such as color, outlines, or transparency, discrepancies between the two models may be more easily perceived.

Fifth, because the present disclosure is applicable to various types of three-dimensional data, such as point clouds, meshes, Gaussian splatting, or 360-degree virtual tours, it has high potential for utilization in various fields, including construction, manufacturing, cultural heritage, or virtual reality.

Consequently, the present disclosure provides the advantage of simultaneously enhancing intuitiveness, accuracy, and user convenience by facilitating a partial superimposition comparison at corresponding positions.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of comparatively displaying three-dimensional models, for displaying a target space on a display device by using first model data and second model data that represent a three-dimensional structure of an object within the same target space, the method comprising:
(a) receiving and storing, by a receiving module, the first model data and the second model data;
(b) aligning, by an alignment module, the first model data and the second model data with each other in the same coordinate system;
(c) displaying, by a first window display module, a model based on the first model data, on a first display window of the display device; and
(d) displaying, by a second window display module, a model based on the second model data, which is aligned with the first model data in the same coordinate system, on a second display window, such that the model based on the second model data is superimposed at a position corresponding to a partial region of the first display window.

2. The method of claim 1, further comprising (e) receiving, by a command receiving module, a position adjustment command for the second display window through an input device,
wherein the operation (d) comprises displaying, by the second window display module, the second display window by adjusting a position of the second display window according to the position adjustment command received in the operation (e).

3. The method of claim 2, further comprising (f) receiving, by the command receiving module, a size adjustment command for the second display window through the input device,
wherein the operation (d) further comprises displaying, by the second window display module, the second display window by adjusting a size of the second display window according to the size adjustment command received in the operation (f).

4. The method of claim 2, further comprising (g) receiving, by the command receiving module, a transparency adjustment command for the second display window through the input device,
wherein the operation (d) further comprises displaying, by the second window display module, the second display window by adjusting a transparency of the second display window according to the transparency adjustment command received in the operation (g) such that the first display window is visible in the background.

5. The method of claim 1, wherein the first model data and the second model data comprise at least one of three-dimensional point cloud data, mesh data, Gaussian splatting data, and 360-degree virtual tour data.

6. The method of claim 1, wherein the first model data is as-built data representing an actual construction state, and
the second model data is building information model (BIM) data representing a design model.

7. The method of claim 1, wherein the operation (c) and the operation (d) comprise displaying the first display window and the second display window in conjunction with each other such that the first display window and the second display window are maintained at the same viewpoint.

8. The method of claim 1, wherein the operation (d) comprises displaying, by the second window display module, the second display window in a form of a virtual lens that enables comparison between the first model data and the second model data through an overlapping area where the second display window overlaps with the first display window, by displaying the model based on the second model data only in a portion corresponding to the overlapping area, while restricting display of the second model data in areas other than the overlapping area through at least one method of masking, clipping, and transparency adjustment.

9. The method of claim 1, wherein the operation (d) comprises displaying, by the second window display module, the second display window such that the model based on the second model data within the second display window is visually distinguished from the model based on the first model data through at least one of different colors, outline display, and transparency settings.
